(19) United States
(12) Patent Application Publication
(10) Pub. No.: US 2025/0068062 A1
(43) Pub. Date: Feb. 27, 2025

(54) Flexible Stamp and Method for Manufacturing a Flexible Stamp

(71) Applicant: Morphotonics Holding B.V., Veldhoven (NL)

(72) Inventors: Jan Matthijs Ter Meulen, Veldhoven (NL); Tim Dekker, Veldhoven (NL); Rob Antonius Waltherus Neelen, Veldhoven (NL)

(21) Appl. No.: 18/729,292

(22) PCT Filed: Jan. 17, 2023
(86) PCT No.: PCT/NL2023/050019

§ 371 Date: Jul. 16, 2024

(30) Foreign Application Priority Data
Jan. 17, 2022 (EP) 22151746.9
Jul. 11, 2022 (EP) 22184125.7

(51) Int. Cl. G03F 7/00; B82Y 40/00

(52) U.S. Cl. CPC G03F 7/0002; B82Y 40/00

(57) ABSTRACT

The invention relates to flexible stamp configured for nanoimprinting, and a method for manufacturing such stamp. The stamp includes a substantially flexible substrate, said substrate including at least one textured area, at least one functional element and at least two conductive tracks which are connected or connectable to at least one functional element.

### CROSS-REFERENCE TO RELATED APPLICATIONS

This application is the United States national phase of International Patent Application No. PCT/NL2023/050019 filed Jan. 17, 2023, and claims priority to European Patent Application Nos. 22151746.9 filed Jan. 17, 2022 and 22184125.7 filed Jul. 11, 2022, the disclosures of which are hereby incorporated by reference in their entireties.

### BACKGROUND OF THE INVENTION

### Field of the Invention

The invention relates to a flexible stamp configured for imprinting, in particular nanoimprinting. The invention also related to a method for manufacturing such stamp. The invention further relates to a system for imprinting, in particular nanoimprinting,

### Description of Related Art

Flexible stamps are used for nanoimprinting processes typically by making use of a roll-to-plate, plate-to-roll or roll-to-roll technique. The stamp is typically a passive working tool which serves as a mould and/or holder for the texture which is to be transferred to product. Especially, it is with the stamps in the current art not possible to react on individual process parameters such as individual pressure or temperature anomalies or randomly occurring gas bubbles underneath the flexible stamp during processing.

### SUMMARY OF THE INVENTION

It is the object of the invention to provide an improved flexible stamp and/or at least an alternative flexible stamp.

The invention provides thereto a stamp, in particular a flexible stamp configured for imprinting, in particular nanoimprinting, comprising at least one substantially flexible substrate, said substrate comprising at least one textured area, at least one functional element, and preferably at least two conductive tracks which are connected or connectable to at least one functional element, wherein at least one functional element substantially (fully) covers and/or overlaps with at least one textured area and/or wherein at least one functional element is positioned outside the textured area.

The stamp according to the present invention benefits of the presence of at least one functional element. Since at least one functional element covers and/or overlaps at least one textured area and/or wherein at least one functional element is positioned outside the textured area the stamp can benefit of the functional element without having said functional element affecting the primary performance of the stamp. It is undesired that the functional element(s) affect(s) the imprinting performance of the stamp. Therefore, the uniform character of the textured area is to be preserved. This is achieved by positioning of the functional element(s) such that they fully cover and/or overlap with the textured area. It can also be achieved by positioning the functional element(s) outside the textured area the stamp. By such mutual configuration of the textured area and the functional element(s) the uniformity of the textured area is maintained. If the functional element only partially covers or overlaps with the textured area of the stamp, irregularities may occur in the texture of the final product. The final product is here the product as imprinted and/or textured by the flexible stamp.

The flexible stamp according to the present invention is in particular configured for imprinting, texturing and/or transferring via roll-to-roll, plate-to-roll and/or roll-to-plate processes. The stamp according to the invention may for example transfer a material such as resin, an ink or a coating material onto a product and thereby provide a layer of material on the product similar to the working principle of an office stamp. In this mode of operation, the textured area of the stamp can be wetted with ink or coating material and then pressed on the surface of the target product in such a manner that on the target product, the parts of the stamp that have been wetted with ink or coating material become visible. Said principle is known as relief imprinting. The stamp may also be brought in contact with a liquid, molten or viscous material either on the stamp itself or on a surface of a target product in such a way that said liquid, molten or viscous material adapts to the texture of the stamp and is hardened e.g. by heating, cooling or by electromagnetic radiation while being in contact with the stamp. Upon removal of the stamp, the negative image of the stamp is then formed in the hardened material which is thus textured like a spot of molten wax on a document by a traditional seal matrix. This imprinting principle is known as intaglio imprinting. The stamp according to the invention may alternatively also be used to transfer small, solid objects such as micro-LEDs from an initial surface to a target surface. No matter whether the stamp is used for imprinting, embossing or transferring, the stamp may have a so-called active area which is the area that is optimized for said imprinting, embossing or transferring function. Typically, the active area substantially equals the textured area. When it is referred to a stamp, also a template or imprinting template can be meant. The substrate according to the invention can also be referred to as carrier, or alternatively as a sheet. The substrate can for example be a sheet of material such as a plate, a panel, a board, a foil, a laminate or a fabric or any other material. The flexibility and/or rigidity depends on the material and the thickness thereof. Preferably, the substrate determines the mechanical properties of a flexible stamp. The functional element can also be referred to as a functional structure. At least one conductive track could also be referred to as a conductive path.

The texture of the textured area is in particular a three-dimensional texture. The textured area may be a three dimensionally textured area comprising depressions and elevations. The textured area may either be a negative or a positive image of a texture to be imprinted into a target product. A positive image of a texture is an image where an elevation on the stamp is transferred into an elevation on the target surface and a depression on the stamp is transferred into a depression on the target surface. A negative image is an image where an elevation on the stamp is transferred into a depression on the target surface and where a depression on the stamp is transferred into an elevation on the target surface.

It is for example possible that at least part of the textured area comprises a repeated pattern. It is also conceivable that at least part of the textured area is a randomized texture. The textured of the textured area may comprise diffractive gratings, slanted gratings, blazed gratings, micro-lens arrays, lenticulars, pillars, bars, pyramids, prism lines and/or combination thereof. It can also be said that the substrate comprises at least one active area, in particular wherein said active area comprises the texture. The active area may differ from the rest of the stamp, and in particular the rest of the substrate.

The depth of the texture of the textured area can for example be in the nanometer to micrometer scale. It is for example conceivable that at least part of the texture has a depth in the range of 0.1 nm to 100 μm. It is also conceivable that at least part of the texture of the textured area comprises a peak to valley height of at most 1 mm. Preferably, at least part of the texture comprises a peak to valley height of at most 10 μm, more preferably at most 5 μm and even more preferably at most 2 μm. However, it is also conceivable that at least part of the texture of the textured area comprises a peak to valley height of at most 100 nm, more preferably at most 50 nm and even more preferably at most 20 or 10 nm.

Typically, within the context of the present invention, the surface of at least one textured area is smaller than the total surface of the substrate. The textured area can for example be centrally located upon or in substrate. The side edge(s) of the substrate are preferably free of texture.

The functional element can for example be applied to monitor, condition or control the process conditions when the same stamp is used during multiple runs. It is for example conceivable in practice that at least part of the stamp, or the substrate, experiences temperature differences during continuous or repeated use. It is for example possible that part of the stamp heats up, which may affect the performance of the stamp. Therefore, at least one function element can be used to compensate and/or counteract for the caused deviations. In a preferred embodiment, at least one functional element is a conductive element, in particular an electrically conductive element. It is also conceivable that at least one functional element is a thermally conductive element or a heating element. It is beneficial to apply at least one conductive element, as in this way the conductive character of the functional element can compensate and/or counteract for any deviations caused during use of the stamp. In this way, a more repeatable result can be obtained, for example identical products or at least products with reduced product deviation. The use of at least one functional element, such as a conductive element may also result in a longer lifespan of the stamp, for example because the functional element can contribute to preservation of the textured area by maintaining optimal process conditions during use of the stamp. The stamp, and in particular the functional element, can for example also be configured such that predetermined pre-conditions which should be met to successfully perform the imprinting process. Monitoring parameters that relate to the pre-conditions is an effective method to gather data, statistics and perform quality control. Non-limiting examples thereof are a functional element monitoring the starting temperature and/or local temperature of the stamp and/or a functional element monitoring the strain on the stamp during the imprint process.

Preferably, at least one functional element encloses at least one textured area. It is also conceivable that at least one functional element defines a functional area. Said functional area may cover, overlap and/or enclose the textured area. The functional area can for example be a conductive area. In a preferred embodiment, the functional area is larger than the textured area. The function area can both fully cover and enclose the functional area, in particular to ensure uniformity of the textured area.

At least part of at least one functional element can be made of at least one conductive material, in particular at least one electrically conductive material. Within this context, an electrically conductive material can for example be classified as a material that does not change its chemical composition while conducting electric energy and which shows an electrical resistivity of 100 (Ωmm\hat{ }2)/m or less. It is beneficial if at least one conductive material comprises at least one metal, at least one non-metallic inorganic compound and/or at least one electrically conductive polymer. It is also conceivable that at least one conductive material comprises a combination of such materials. Non-limiting examples of metals which can be applied are iron, aluminium, copper, silver, gold, tin or any alloy thereof. It is also conceivable that at least one (electrically) conductive material comprises a non-metallic inorganic compound or element such as but not limited to graphite, graphene, carbon nanotubes, carbon fibers and/or niobium oxide. The electrically conductive material may furthermore be an electrically conductive polymer such as polyacetylene, poly-3,4-ethylendioxythiophen, polypyrrole or any other electrically conductive polymer known to the person skilled in the art. It is for example conceivable that at least one functional element comprises wires and/or ribbons. At least one functional element may comprise a mesh of conductive material and/or a wire mesh.

It is also conceivable that at least one conductive material comprises at least one doped metal oxide. At least one doped metal oxide can for example be chosen from the group of: indium-tin oxide (ITO), antimony-doped tin oxide (ATO), aluminium-doped zinc oxide (AZO), indium doped zinc oxide (IZO) and/or gallium doped zinc oxide (GZO). Such materials benefit of a relatively good transparency and/or being substantially translucent. This is beneficial as the material then would not significantly affect radiation through the material which might be needed for the imprinting process in which the stamp is applied. Preferably, at least part of the functional element which covers and/or overlaps with the textured area is substantially transparent and/or translucent.

Preferably, at least part of at least one substrate is substantially transparent and/or translucent, in particular for visible light and/or UV radiation and/or infrared radiation. Preferably at least the part of the stamp, and in particular the substrate, is substantially transparent and/or translucent at the location of the (entire) textured area. This is of relevance for ensuring that radiation through the material, and in particular through the textured area, is not affected. Typically, a rear side of the substrate, opposite of the side having the textured area is substantially transparent such that radiation though the material is facilitated. Preferably, if at least one functional element substantially fully covers the textured area, the optical properties, for example the transparency and/or reflectivity, of the functional element differ by at most 5% to the optical properties of the textured area. At least part of the substrate preferably has a transparency of at least 10%, preferably at least 50%, more preferably at least 90%. At least part of the substrate preferably has an UV-A transparency, or UV-A permeability, of at least 60%. It is for example conceivable that at least part of the substrate has an UV-A transparency in the range of 60% to 100%, in particular in the range of 70% to 90%.

The substrate may comprise at least one polymer. It is for example conceivable that at least part of at least one substrate comprises polyethylene terephthalate, polyethylene naphthalate, polycarbonate and/or polyimide. Other non-limiting examples of polymer which could be applied are poly(methyl methacrylate), polyethylene, polypropylene and/or cyclo olefin polymers. Such materials are known for their good flexible properties. Alternatively, or additionally, at least one substrate may comprise metal and/or glass, for example a metal sheet and/or glass sheet. Metal and/or glass could also be applied as particles dispersed in the polymer, in particular for strengthening purposes. In a possible embodiment, the substrate may be a laminate of several foils of the same or different polymeric materials. Alternatively, the substrate may be a laminate of a plastic foil and glass panels and/or metal sheets.

The flexible stamp according to the present invention is typically relatively thin. The stamp may for example have a thickness of at most 1000 μm, in particular at most 750 μm, more in particular at most 500 μm. At least one substrate has a thickness of at most 500 μm, preferably at most 400 μm, more preferably at most 300 μm. It is also conceivable that at least one substrate has a thickness of at most 250 μm, preferably at most 200 μm, more preferably at most 175 μm. The thickness of the substrate is preferably substantially uniform. In particular, the thickness of the substrate at the textured area is substantially uniform. Any difference in thickness could affect the performance of the stamp. The stamp, and in particular the substrate, is preferably bendable to a radius of 50 cm or smaller, or to a radius of 20 cm or smaller. The stamp is preferably configured such that bending is performed without damaging the stamp and/or without permanently deforming the stamp. Controlling the bendability of the substrate can be useful for any internal and/or external electrical contacts. At least one substrate can for example have a bending radius in the range of 5 to 50 cm, for example 10 to 40 cm and/or 20 to 30 cm. It is also conceivable that the substrate has a bending radius of r with 0 cm<r<50 cm.

It is also conceivable that at least one substrate has a Youngs modulus of less than 10 GPa, preferably less than 4 GPa, preferably less than 3 GPa, more preferably less than 2 GPa. It is also conceivable that at least one substrate has a Youngs modulus of less than 80 GPa, preferably less than 40 GPa, preferably less than 10 GPa, more preferably less than 2 GPa. It is also conceivable that the Youngs modulus is in range of 0.1 to 200 GPa, in particular in the range of 40 to 80 GPa The Youngs Modulus is for example measured according to ASTM E111. Such embodiment facilitates a sufficient flexibility whilst the textured area is not affected. The flexibility of at least one functional element may be the same or higher than the flexibility of the substrate.

In a possible embodiment, at least one functional element comprises at least one electrical component. It is also possible that at least one functional element is an electrical component. At least one electric component can for example be an RFID unit or RFID element or RFID chip. It is also possible that at least one functional electric component is a pixilated functional electrical component. In an embodiment, the stamp may comprise at least one functional electrical component. A functional electrical component may either be any component or device which converts electrical energy into a different form of energy and thereby carries out a function such as e.g. heating, light emission, mechanical actuation or force fields or carries out the function to determine changes in current or voltage acting as sensor determining for instance changes in stamp stretch, temperature or pressure. A functional electrical component for heating may e.g. be an electrical resist heater or a Peltier device which may be used for electrical heating and cooling. Using an electrical resist heater or a Peltier device, the viscosity of resin underneath or in the vicinity of the stamp may be influenced or the resin may thermally be cured. A functional electrical component for light emission may e.g. be a light-emitting diode. In an embodiment, the light emitting diode comprised in the stamp is a thin-film light-emitting diode or a flexible thin-film light emitting diode. Using a functional electrical component for light emission, a resin underneath the stamp may be cured or otherwise hardened, e.g. by cooling, UV radiation, evaporation of a solvent or heating. A functional electrical component suitable for mechanical action may be an actuator such as a piezo actuator or dielectric elastomer which may either carry out vibrational or translatory movements. Using a functional electrical component suitable for mechanical action, several functionalities may be carried out. Vibrational movements may be used to emit gas bubbles from resin underneath the stamp in a similar manner as ultrasound is used for degassing. Furthermore, by movements the rheological properties such as the viscosity of a resin underneath or in the vicinity of the stamp may be influenced. Actuators such as piezo actuators may furthermore also be used as grippers comparable to tweezers to grip and to release small pieces of solid material. A functional electrical element converting electrical energy into a force field may e.g. be a capacitor plate which is embedded into the stamp which then also serves as part of a dielectric material separating the capacitor plate within the stamp from a second capacitor plate or an item serving as second capacitor plate outside the stamp. Upon application of voltage between said two capacitor plates, an electrical field may be formed between the inside and the outside of the stamp which may be used to e.g. electrostatically bind items such as small pieces of solid material to the stamp. Another functional electric device converting electrical energy into a force field may be an inductivity which forms a magnetic field if electricity flows therethrough. Said magnetic field may be used to selectively bind and release items to and from the stamp.

A sensor may convert physical effects such as strain, pressure, temperature or light into an electrical signal which may be amplified for detection. Said functional electrical component and/or sensor may be located in parts or in the whole active area of the stamp and e.g. heat the whole area where it is located or detect the pressure being exerted to the stamp or the strain exerted to the stamp either inside or outside the active area. The stamp according to the present application may comprise one or more sensors. At least one functional element can be a pixilated functional element. In an embodiment, the functional electrical component is pixilated which means that not one large functional electric device is comprised in the stamp but that the active area of the stamp or parts thereof are tiled by a plurality of small functional electrical components which selectively may be switched on and off and/or steered and may thus carry out their functions at specific locations. The pixilated electrical component may e.g. be pixilated heating pads, pixilated gripper arrays, pixilated piezo actuators, pixilated light sources or any combination thereof. Actuators such as piezo actuators may further be used as ultrasonic heaters for lowering the viscosity of resin underneath or in the vicinity of the stamp. The sensors may be pixilated and thus, the stamp may comprise pixilated pressure sensors such as load cell arrays, pixilated strain sensors, pixilated temperature sensors or pixilated light sensors or any combination thereof. Said pixilated sensors may allow for specific detection of said physical effects for regions under the stamp. A pixilated functional electrical component or a pixilated sensor according to the application is a functional electrical component or a sensor which is comprised in the stamp at least twice with the two devices having no spatial overlap and with the two devices being able to be used selectively for the region they are covering. Throughout this application, the term “pixilated” is not to be understood in such a way that the elements of a pixilated device have to form a closed area or are in direct vicinity to each other. Elements of a pixilated device may be distributed over an area with space between different elements which may be a multiple of the size of the elements.

In an embodiment, the stamp may comprise a combination of pixilated sensors and pixilated functional electric components. In an embodiment at least two sensors might be placed symmetrically at both sides of the active area for example along the imprint direction. In an embodiment at least two sensors might be placed in a row at one or both sides of the active area across the imprint direction also called as the start or stop side of the stamp. In an embodiment the sensors might be placed in a circle surrounding the active area or active areas.

The stamp may further comprise an electric circuit. In an embodiment, the electric circuit steers the functional electrical components and/or the sensors in the stamp, no matter whether they are pixilated or not. The electric circuit may steer the functional electrical components based on data provided by the sensors. In an embodiment, the stamp may comprise an RFID unit which can inductively be contacted by a control device out of the stamp. The RFID unit may be used to store information on e.g. the type of the stamp, the number of use cycles or the amount of thermal, pressure or strain stress the stamp has been exposed to. Using RFID devices, stamps could be recognizable for the imprinting, embossing or transfer system in which they are running being used. The stamp may comprise at least three electrical contacts, whereof one may be used for power connection (also called VVC), one as data connection and one as common return part (often called ground or GND). The electrical contacts may have the form of a serial or parallel bus. The properties of the stamp may change depending on position in a machine, on an imprinting the substrate that is to be provided with and imprint substrate and/or according to data read from sensors comprised in the stamp. The stamp may comprise a pixilated heating pad and may be heated depending on position under use stamp position and/or process step and/or imprinting setting. The stamp may comprise a pixilated piezo element and may be actuated depending on position under use in order to e.g., create shockwaves or vibrations in a resin to promote the driving out expel unwanted gas in the resin or gas present in the resin layer or between the resin and the stamp of air bubbles. The stamp may comprise a pixilated gripper array which may be actuated depending on the position under use. The stamp may comprise a pixilated loadcell array and loadcell data may be adjusted depending on the position under use. The stamp may comprise a pixilated light source and light emission e.g., for curing or detection purposes may be adjusted depending on the position under use. The stamp may be powered and/or controlled via galvanic contacts. The contact with the source can be made for instance in the clamps which are used to also fix the stamp mechanically to a roller, a belt, a chuck or any other part of an imprinting, texturing, or transferring device. The stamp may be powered and/or controlled via a wire mounted on the galvanic contacts on the stamp. The stamp may be powered and/or controlled via sliding contacts. The stamp may be powered and/or controlled via capacitive coupling e.g., in the clamp or on a roller. The stamp may be powered and/or controlled via inductive coupling. Powering and/or controlling via inductive and/or capacitive coupling is carried out via devices which are in the present application also understood to be “electrical contacts” although they are not in a direct material contact but only in contact through electrical and/or magnetic fields.

It is preferred that at least one functional element comprises at least one sensor. The use of at least one sensor can add further functionality and/or controllability to the stamp. It is for example conceivable that at least one sensor is a temperature sensor, a strain sensor, pressure sensor, position sensor, force sensor, piezo sensor, humidity sensor or an optic sensor. It is also possible that a plurality of sensors is applied, which can be the same or different sensors. It is further imaginable that at least one functional element is chosen from the group of: a heating element, a load cell array, a gripper array, a strain sensor, a recognition tag, RFID tag, a temperature sensor and/or a piezo element. Non-limiting examples of piezo elements which can be applied are a piezo actuator, a light-emitting diode, a capacitor and/or any combination thereof. It is for example possible that the stamp comprises multiple sensors, for example pressure and/or temperature sensors, which are distributed over the substrate, wherein each sensor is positioned outside the textured area. It is also possible that at least one functional element is a heating element such as a heating pad. Possibly, at least one functional element comprises at least one electric circuit. The stamp may further comprise, or cooperate with, at least one control unit which can adjust at least one functional element based upon data obtained during use of the stamp.

In a beneficial embodiment, at least one functional element is provided upon a surface of the substrate. At least one functional element can for example be attached to the surface of the substrate. It is also conceivable that at least one functional element is provided via deposition, sputtering and/or printing. At least one functional element can be at least partially embedded in the substrate. Hence, it is possible that at least part of at least one functional element is embedded in the substrate and that a further part of the functional element is present at a (n) (outer) surface of the substrate. Typically, at least one substrate comprises front surface and a rear surface. It is possible that at least part of at least one functional element is at the rear surface of the substrate and that the textured area at the front surface of the substrate. In this way, the functional element can be at a distance from the textured area. It is also conceivable that at least one functional element is on the same side of the substrate, but such that the functional element does not overlap and/or interfere with the textured area.

The stamp may also comprise multiple functional elements. It is conceivable that the stamp comprises at least two functional elements. The stamp may also comprise a plurality of functional elements. This can be the same (type of) functional elements. It is also conceivable that the stamp comprises multiple functional elements, wherein at least two different types of functional elements are present. Hence, it is for example conceivable that at least one functional element comprises a conductive element and that at least one functional element comprises a sensor. It is imaginable that at least one functional element fully covers and/or overlaps with at least one textured area and that at least one further functional element is positioned outside the textured area. In case multiple functional elements are applied, it is conceivable that at least two functional elements are actuated individually. It is also conceivable that at least two functional elements are placed in parallel and/or in series.

At least part of at least one textured area is preferably imprinted upon the substrate. It is for example conceivable that at least one textured area is imprinted into a layer of resin on the substrate.

At least one conductive track, and preferably each conductive track is positioned at a distance from the textured area. In this way, the conductive track(s) would not affect the performance of the textured area and/or the physical properties of the stamp, such as transparency, stiffness or conductivity. At least part of the functional element can be positioned outside of a surface defined by the textured area, such that a connection between the conductive track(s) and the functional element can be made at a distance from the textured area. Said distance, between the textured area and at least one conductive track is preferably at least 0.1 μm or 0.5 μm.

At least one, and preferably each conductive track is connected or connectable to at least one functional element. In this way the conductive track can provide a contact, in particular an electrical contact, between the functional element and a further component. At least one conductive track could for example serve as energy supply for the functional element. It is for example conceivable that at least part of at least one conductive track is provided upon a surface the substrate. This can for example be done via deposition, sputtering and/printing. It is also conceivable that at least one, or each, conductive track comprises a wire, in particular a printed wire. It is also conceivable that at least part of at least one conductive track is embedded in the substrate. In case multiple conductive tracks are applied, it is desirable that the tracks do not interfere. It is for example possible that at least one insulating element is applied in case tracks would overlap. Hence, it is possible that tracks cross and/or overlap via the interference of at least one insulating element. At least one conductive track could also operate as data connection.

The stamp may further comprise at least two contacts, in particular electrical contacts. Preferably at least one, and in particular each (electrical) contact is connected to or connectable with at least one conductive track. The contact, or electrical contact, can for example be a contact area defined upon or within the stamp, in particular the substrate. It is conceivable that the stamp comprises at least two electrical contacts which are directly or indirectly connected or connectable to at least one functional element. The electrical contact can for example be connected to at least one functional element via the conductive tracks. Possibly, at least one electrical contact is at least partially galvanic, capacitive and/or inductive. It is also conceivable that at least one electrical contact is comprised in a clamping element. At least one clamping element, or clamp can for example allow for mechanical and/or electrical attachment of the stamp to an imprinting, texturing or transferring apparatus.

The stamp may further comprise at least one power supply. Such power supply may for example be an internal power supply, possibly embedded within the substrate. It is also conceivable that the stamp comprises an external power supply. Non-limiting examples of power supplies are a battery, a photovoltaic cell, an electromagnetic coil for inductive power transfer or any combination thereof. The stamp may comprise a device to electronically count process cycles.

The invention also relates to a system for imprinting, in particular nanoimprinting, configured for retaining at least one stamp according to the present invention and said system comprising at least one steering structure for electrical steering of the stamp. The invention also relates to a system for imprinting and/or texturing, in particular nanoimprinting, comprising at least one stamp according to the present invention and/or at least one steering structure for electrical steering of the stamp. The system for imprinting and/or texturing is preferably configured for retaining at least one stamp according to the present invention. At least one steering structure may be configured to hold and/or electrically steer the stamp. It is for example conceivable that at least one steering structure is configured to be in (direct) contact with at least one conductive track of the stamp. The steering structure may comprise at least one printed, galvanic, capacitive and/or inductive electrical connection element. The system may for example also comprise at least one retaining element for retaining at least one stamp. The system may be configured for wafer-scale, roll-to-roll or roll-to-plate imprinting. The steering structure may comprise at least one steering belt, preferably a plurality of steering belts. For example, a pair of steering belts can be applied wherein the belts are located on opposing sides of the stamp. The steering structure may comprise a clamping element configured to hold and/or electrically steer the stamp. The clamping element may comprise an upper lid, a bottom lid and two screw elements configured to clamp the stamp between the upper lid and the bottom lid. The clamping element may further comprise electrical conducting contacts which are configured to be connected to corresponding contacts on the stamp. The camping element can be mounted to the steering belt, if applied. The system may comprise contact areas for energy supply to the stamp, said contact areas can for example be provided upon a sliding rail. When it is referred to a steering belt also a sliding rail can be meant, or vice versa. In an embodiment, the system according to the invention has the ability to steer the electrical current on the stamp. In this particular embodiment, the flexible stamp comprises electrical contacts which extend from the flexible stamp and are connected to corresponding electrical contacts of the system. Said electrical contacts of the system are connected to an electrical power source which is either steerable by itself or within the connection between the power source and the electrical contacts of the system, a means for steering electrical power such as a potentiometer or transistor or any array or combination thereof is installed. In an embodiment, steering is possible through a wire. In an embodiment, steering is possible through adoptions in the manner the flexible stamp is mounted into the system. In this embodiment, the system may comprise several electric contacts providing electrical power in different voltages and/or electric current intensities. In an embodiment, the electrical connection between the system and the flexible stamp is realized through sliding contacts such as carbon brushes or current collectors. The system may comprise contacts shaped like conductor rails while the flexible stamp comprises carbon brushes or current collectors similar to electric trains which make up an electrical connection between the system and the flexible stamp. In an embodiment, the electrical connection between the system and the flexible stamp is formed using a capacitive or inductive connection or any combination thereof. For an inductive connection, the system comprises an inductivity e.g. in the form of an electrical coil as a transmitter and the flexible stamp comprises an inductivity e.g. in the form of an electrical coil as a receiver.

For a capacitive coupling, both the flexible stamp and the system may comprise two capacitor plates which may be combined in such a way that two capacitors are formed between the system and the flexible stamp. Application of a voltage between the two capacitor plates in the system may then lead to a current flow between the two capacitor plates in the flexible stamp via capacitive coupling.

The invention also relates to a flexible stamp configured for imprinting, in particular nanoimprinting, comprising at least one substantially flexible substrate, at least one textured area, at least one functional element and preferably at least two conductive tracks which are connected or connectable to at least one functional element, wherein at least one functional element fully covers and/or overlaps with at least one textured area and/or wherein at least one functional element is positioned outside the textured area. This embodiment can be combined with any of the embodiments as described.

The invention also relates to a method for manufacturing a stamp in particular configured for imprinting and/or texturing, in particular nanoimprinting, preferably a stamp according to the present invention, said method comprising the steps of providing at least one substantially flexible substrate and providing said substrate with at least one textured area, at least one functional element and at least two conductive tracks which are connected or connectable to at least one functional element, such that at least one functional element fully covers and/or overlaps at least one textured area and/or such that at least one functional element is positioned outside the textured area.

The method provides for the manufacturing of a stamp according to the present invention. Any of the embodiments described for the stamp may apply to the method. Preferably, at least one textured is imprinted upon the substrate, in particular after the substrate is provided with at least one functional element and/or at least two conductive tracks. In this way, the provision of at least one function element and/or conductive track will not affect the (rather fragile) texture of the substrate. Also, it ensures alignment of the imprinted texture or textures in relation to the functional element.

### BRIEF DESCRIPTION OF THE DRAWINGS

The terms Fig., Figs., Figure, and Figures are used interchangeably in the specification to refer to the corresponding figures in the drawings.

The invention will be further elucidated by means of non-limiting exemplary embodiments illustrated in the following figures, in which:

FIG. 1 shows a schematic representation of a first possible embodiment of a stamp according to the present invention;

FIG. 2 shows a schematic representation of a second possible embodiment of a stamp according to the present invention;

FIG. 3 shows a schematic representation of a third possible embodiment of a stamp according to the present invention;

FIG. 4 shows a schematic representation of a flexible stamp mounted into a system during use;

FIG. 5 shows part of a system using a stamp according to the invention; and

FIG. 6 shows a schematic representation of an imprinting process using a stamp according to the present invention.

Within these figures, similar reference numbers correspond to similar or equivalent elements or features.

### DESCRIPTION OF THE INVENTION

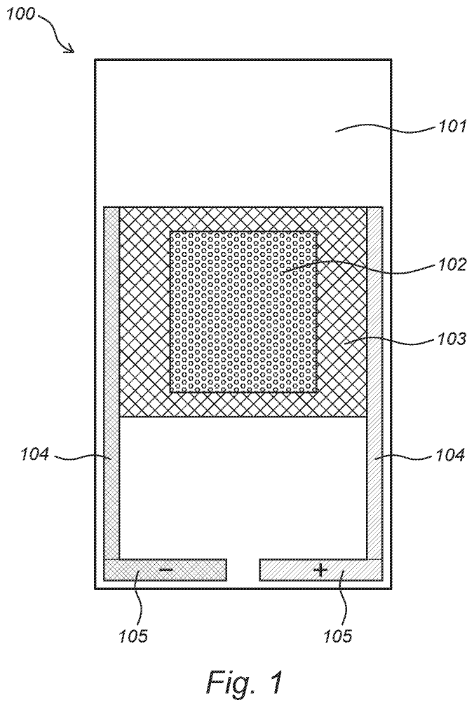

FIG. 1 shows a schematic representation of a first possible embodiment of a stamp 100 according to the present invention. The stamp 100 is a flexible stamp 100 configured for imprinting, in particular nanoimprinting, comprising a substantially flexible substrate 101, said substrate 101 comprising at least one textured area 102. The stamp 100 further comprises a functional element 103 and two conductive tracks 104 which are connected to the functional element 103. The stamp 100 as shown further comprises two electrical contacts 105, wherein each electrical contact 105 is connected a conductive track 104. In the shown embodiment, the functional element 103 fully covers and overlaps with the textured area 102. The conductive tracks 104 are positioned at a distance from the textured area 102. The textured area 102 only covers part of the substrate 101, and is substantially centrally located. The substrate 101 is in particular substantially transparent and/or translucent. The functional element 103 defines a functional area which is substantially uniform. The functional element 103 can for example be substantially positioned behind the textured area 102. The functional element 103 can be substantially transparent and/or translucent.

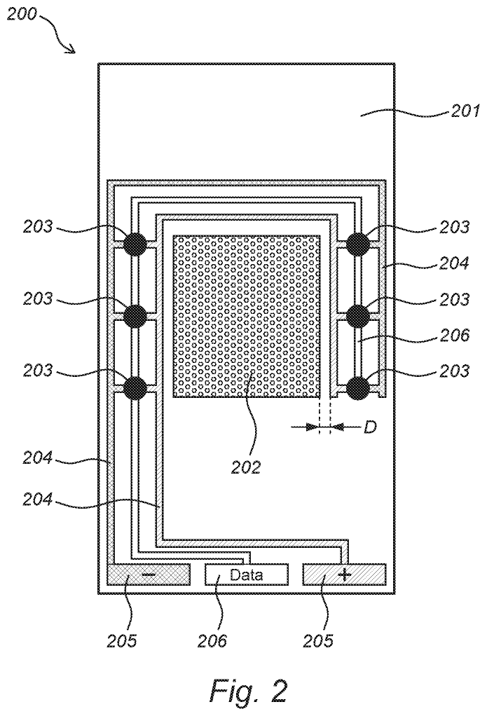

FIG. 2 shows a schematic representation of a second possible embodiment of a stamp 200 according to the present invention. The stamp 200 comprises a substantially flexible substrate 201, said substrate 201 comprising a textured area 202. The stamp 200 further comprises multiple functional elements 203 and two conductive tracks 204 which are connected to the functional elements 203. The stamp 200 as shown further comprises two electrical contacts 205, wherein each electrical contact 205 is connected a conductive track 204. The stamp 200 also comprises a data track 206 and a data connector 206 for obtaining data during use of the stamp. It is also possible that the data track 206 substantially equals the conductive track. In the shown embodiment, the functional elements 203 are positioned outside the textured area 202. The functional elements 203 are in particular sensors 203, for example pressure sensors 203. The conductive tracks 104 are positioned at a distance D from the textured area 102.

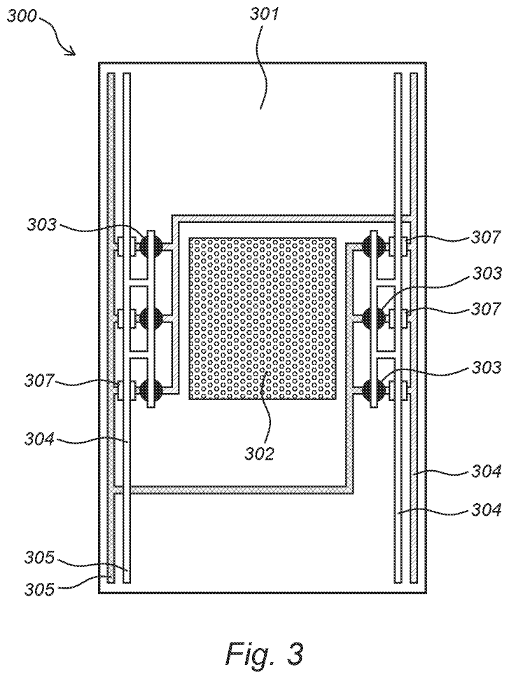

FIG. 3 shows a schematic representation of a third possible embodiment of a stamp 300 according to the present invention. The stamp 300 comprises a substantially flexible substrate 301, said substrate 301 comprising a textured area 302. The stamp 300 further comprises multiple functional elements 303 and two conductive tracks 304 which are connected to the functional elements 303. The stamp 300 comprises electrical contacts 305 which are integrated in the conductive tracks 304. The stamp 300 further comprises insulating elements 307 at locations where the conductive tracks 304 would otherwise cross or overlap. The conductive tracks 304 could serve as energy supply for the functional elements 304. At least one of the conductive tracks 304 can also be used as data connection to the functional element(s) 303.

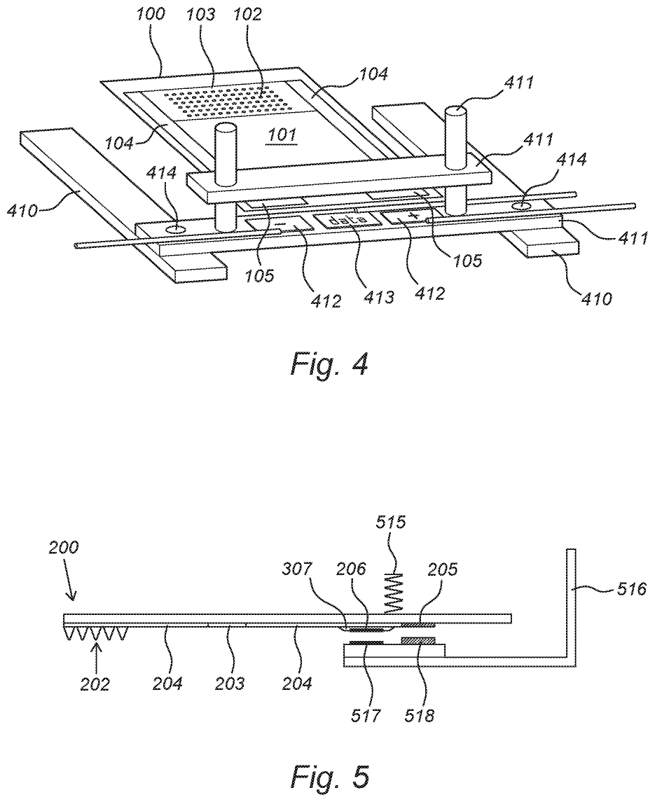

FIG. 4 shows a schematic representation of the flexible stamp 100 as shown in FIG. 1 being mounted into a system according to the present invention. The system comprises steering structure 410, in particular steering belts 410 using a clamping element 411, or clamp 411 to hold and electrically steer the flexible stamp 100. The clamp 411 as shown comprises an upper lid, a bottom lid and two screw elements configured to clamp the stamp 100 between the upper lid and the bottom lid. The clamp 411 further comprises electrical conducting contacts 412 which are connected to corresponding contacts 105 on the flexible stamp 100. The clamp 411 is further mounted to the steering belt 410 via mounting elements 414. Furthermore, the clamp 411 comprises wires to an energy source and wires to a data source which may connect the data contact 413.

FIG. 5 shows a schematic representation of a system equivalent to the system as shown in FIG. 4, wherein a flexible stamp 200 as shown in FIG. 2 and/or FIG. 3 is applied for an imprinting process. The contact areas 205, 206 for energy supply are connected to a contact for energy supply 517, 518 on a sliding rail 516 of the system.

Contact between the contacts 205, 206 on the stamp 200 and the contact areas 517, 518 on a sliding rail 516 is assured by a spring 515 which presses the contacts 205, 206 against the sliding rail 516.

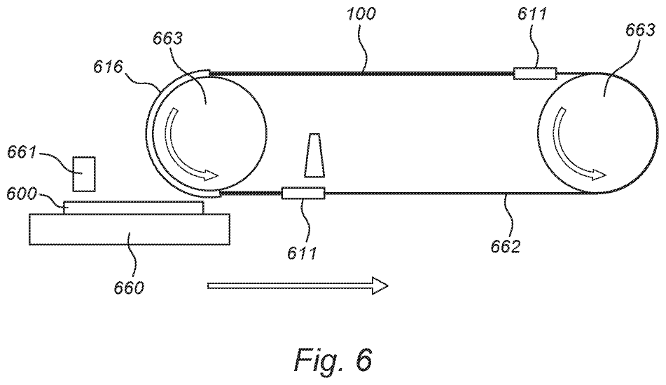

FIG. 6 shows a schematic representation of an imprinting process using a flexible stamp 100 according to the present invention. A product 600 to be imprinted is shown too, which product is positioned upon a carrier 660. A lacquer or resin is provided via an application unit 661. The textured area of the flexible stamp 100 is covered by a layer of lacquer or resin before said textured area is brought into contacted with the target product 660. The target product 660 is conveyed underneath the flexible stamp 100 on a carrier 660. It must be noted that layer of lacquer or resin could also have been deposited on the stamp 100 instead of on the product 660, or on both. The flexible stamp 100 is fixed to a belt 662 using clamps 611. The belt 662 and the flexible stamp 100 are conducted by rollers 663. In the proximity of a roller 663, the sliding rail 616 is mounted. The exact position of the sliding rail 616 can vary and is determined by the moment of contact point with the flexible stamp 100, for example in order to enable an electrical circuit to be electrical steered.

It will be clear that the invention is not limited to the exemplary embodiments which are illustrated and described here, but that countless variants are possible within the framework of the attached claims, which will be obvious to the person skilled in the art. In this case, it is conceivable for different inventive concepts and/or technical measures of the above-described variant embodiments to be completely or partly combined without departing from the inventive idea described in the attached claims.

The verb ‘comprise’ and its conjugations as used in this patent document are understood to mean not only ‘comprise’, but to also include the expressions ‘contain’, ‘substantially contain’, ‘formed by’ and conjugations thereof.

1. A flexible stamp configured for nanoimprinting, comprising:
at least one substantially flexible substrate, said substrate comprising at least one textured area;
at least one functional element; and
at least two conductive tracks which are connected or connectable to at least one functional element;
wherein at least one functional element fully covers and/or overlaps with at least one textured area and/or wherein at least one functional element is positioned outside the textured area.

2. The stamp according to claim 1, wherein at least one functional element is a conductive element, in particular an electrically conductive element and/or a thermally conductive element.

3. The stamp according to claim 1, wherein at least one functional element defines a functional area, wherein said functional area covers and/or encloses said textured area.

4. The stamp according to claim 1, wherein at least part of at least one functional element is made of an electrically conductive material, wherein the at least one conductive material comprises at least one metal, at least one non-metallic inorganic compound and/or at least one electrically conductive polymer.

5. (canceled)

6. The stamp according to claim 1, wherein at least one conductive material comprises at least one doped metal oxides, preferably chosen from the group of: indium-tin oxide, antimony-doped tin oxide, aluminium-doped zinc oxide, indium doped zinc oxide and/or gallium doped zinc oxide.

7. The stamp according to claim 1, wherein at least part of at least one substrate is substantially transparent and/or translucent.

8. The stamp according to claim 1, wherein at least part of at least one substrate comprises polyethylene terephthalate, polyethylene naphthalate, polycarbonate, polyimide poly(methyl methacrylate), polyethylene, polypropylene and/or cyclo olefin polymers.

9. The stamp according to claim 1, wherein at least one substrate has a thickness smaller than 500 μm or smaller than 400 μm or smaller than 300 μm and/or wherein at least one substrate has a bending radius in the range of 5 cm to 50 cm and/or wherein at least one substrate has a Youngs modulus of less than 80 GPa or less than 40 GPa or less than 10 GPa.

10-13. (canceled)

14. The stamp according to claim 1, wherein at least one functional element is chosen from the group of: an electrical component, a heating element, a load cell array, a gripper array, a sensor, a strain sensor, a temperature sensor, a recognition tag, RFID tag and/or a piezo element.

15. The stamp according to claim 1, wherein at least one functional element comprises at least one electric circuit.

16. The stamp according to claim 1, wherein at least one functional element is provided upon a surface the substrate and/or wherein at least part of at least one functional element is embedded in the substrate.

17. (canceled)

18. The stamp according to claim 1, wherein at least one substrate comprises a front surface and a rear surface, wherein at least one further functional element is at the rear surface of the substrate and the textured area is at the front surface.

19. The stamp according to claim 1, comprising multiple functional elements, wherein at least one functional element fully covers and/or overlaps with at least one textured area and wherein at least one functional element is positioned outside the textured area.

20. (canceled)

21. (canceled)

22. The stamp according to claim 1, wherein at least part of at least one conductive track is provided upon a surface the substrate and/or wherein at least part of at least one conductive track is embedded in the substrate and/or wherein at least one conductive track is positioned at a distance from the textured area.

23. (canceled)

24. The stamp according to claim 1, comprising at least two electrical contacts, wherein each electrical contact is connected to or connectable with at least one conductive track.

25. The stamp according to claim 24, wherein at least one electrical contact is at least partially galvanic, capacitive and/or inductive.

26. The stamp according to claim 1, wherein at least one electrical contact is comprised in a clamping element.

27. (canceled)

28. A method for manufacturing a stamp configured for nanoimprinting according to claim 1, said method comprising the steps of providing at least one substantially flexible substrate and providing said substrate with at least one textured area, at least one functional element and at least two conductive tracks which are connected or connectable to at least one functional element, such that at least one functional element fully covers and/or overlaps at least one textured area and/or such that at least one functional element is positioned outside the textured area.

29. The method according to claim 28, wherein the textured area is imprinted upon the substrate after the substrate is provided with at least one functional element and/or at least two conductive tracks.

30. A system for nanoimprinting, configured for retaining at least one stamp according to claim 1 and said system comprising at least one steering structure for electrical steering of the stamp.
